(19) United States
(12) Patent Application Publication
(10) Pub. No.: US 2018/0061814 A1
(43) Pub. Date: Mar. 1, 2018

(54) BACKLIGHT SYSTEM AND METHOD FOR MANUFACTURING THEREOF

(71) Applicant: HON HAI PRECISION INDUSTRY CO., LTD., New Taipei (TW)

(72) Inventors: KUO-SHENG LEE, New Taipei (TW); WEI-CHIH CHANG, New Taipei (TW); CHUNG-WEN LAI, New Taipei (TW); PO-FU CHEN, New Taipei (TW); SHENG-HAN LI, New Taipei (TW); CHIH-HAO CHANG, New Taipei (TW)

(21) Appl. No.: 15/690,170

(22) Filed: Aug. 29, 2017

Related U.S. Application Data
(60) Provisional application No. 62/381,004, filed on Aug. 29, 2016.

(51) Int. Cl. H01L 25/075; H05B 33/08

(52) U.S. Cl. CPC H01L 25/0753; H01L 33/502; H05B 33/0851

(57) ABSTRACT

A backlight system includes a backlight module. The backlight module includes a light source array with a plurality of micro LEDs. The backlight module defines a plurality of lighting regions having a constant size. A number of the micro LEDs in each lighting region is random. The micro LEDs in each lighting region comprises a plurality of positive micro LEDs located in a forward manner and a plurality of negative micro LEDs located in a reverse manner.

### CROSS-REFERENCE TO RELATED APPLICATIONS

This application claims priority to U.S. Provisional Application No. 62/381,004 filed on Aug. 29, 2016, the contents of which are incorporated by reference herein.

### FIELD

The subject matter herein generally relates to a backlight system and a method for manufacturing a backlight system.

### BACKGROUND

Micro light emitting diode (micro LED) display has advantages of low power consumption. Due to the size of the micro LEDs, the micro LEDs are prepared on a substrate using a micro-transfer printing manner. For achieving a uniformity of the light source, the position of the micro LEDs needs to be accurately placed. However, the manufacture method is complicated. Improvement in the art is preferred.

### BRIEF DESCRIPTION OF THE FIGURES

Implementations of the present disclosure will now be described, by way of example only, with reference to the attached figures.

FIG. 1 is a diagram of a first exemplary embodiment of a backlight system, the backlight system comprises a backlight module and a backlight driving module.

FIG. 2 is a cross-sectional view of the backlight module of FIG. 1, taking along line II-II, the backlight module comprises a plurality of positive micro light emitting diodes (LEDs).

FIG. 3 is a cross-sectional view of an exemplary embodiment of the positive micro LED of FIG. 2.

FIG. 4 is a top view of an exemplary embodiment of the positive micro LED of FIG. 2.

FIG. 5 is a diagram of a second exemplary embodiment of a backlight system, the backlight system comprises a backlight module.

FIG. 6 is a cross-sectional view of the backlight module of FIG. 5, taking along line VI-VI.

FIG. 7 is a diagram of a third exemplary embodiment of a backlight system, the backlight system comprises a backlight module.

FIG. 8 is a cross-sectional view of the backlight module of FIG. 7, taking along line VIII-VIII.

FIG. 9 is a cross-sectional view of a fourth exemplary embodiment of the backlight module of FIG. 1, taking along line II-II.

FIG. 10 is a diagram view of an exemplary embodiment of the backlight driving module of FIG. 1.

FIG. 11 is a flowchart view of a method of manufacturing the backlight module of FIG. 1, the method having blocks S1-S5.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the exemplary embodiments described herein.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series, and the like. In general, the word “module,” as used herein, refers to logic embodied in hardware or firmware, or to a collection of software instructions, written in a programming language, for example, Java, C, or assembly. One or more software instructions in the modules may be embedded in firmware, such as an EPROM. It will be appreciated that modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage systems. Exemplary embodiments of the present disclosure will now be described in detail with reference to the drawings.

The present disclosure provides a backlight system with a plurality of micro light emitting diodes (micro LEDs) as a backlight source for providing planar light. The backlight system can be embedded in a display device as a backlight source. The backlight system includes a backlight module and a backlight driving module. The backlight module includes a light source array with a plurality of micro LEDs arranged on a same layer. A density of the micro LEDs per unit area is random. In other words, the light source array defines a plurality of lighting regions. Each lighting region corresponds to the multiple micro LEDs. The number of the micro LEDs in each lighting region is random, such as a number of the micro LEDs in each lighting region are different from each other, or a number of the micro LEDs in some of the lighting regions are equal. Some of the micro LEDs does not emit light. The backlight driving module adjusts an intensity of each lighting region to ensure a uniformity of the backlight module. The term “micro” LED means a descriptive size of the LED, the “micro” refers a scale of 1-100 μm. However, it is to be appreciated that exemplary embodiments of the present invention are not necessarily so limited, and that certain aspects of the exemplary embodiments may be applicable to larger, and possibly smaller size scales. The backlight module further includes a plurality of optical films based on a design requirement of the backlight system, such as an enhancement film and a diffusion film.

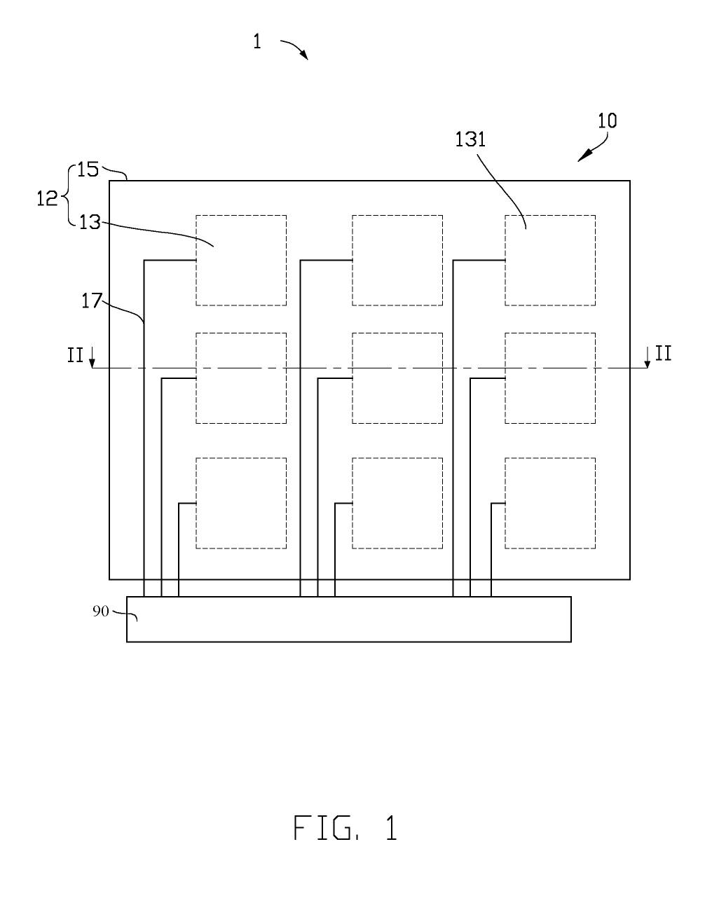

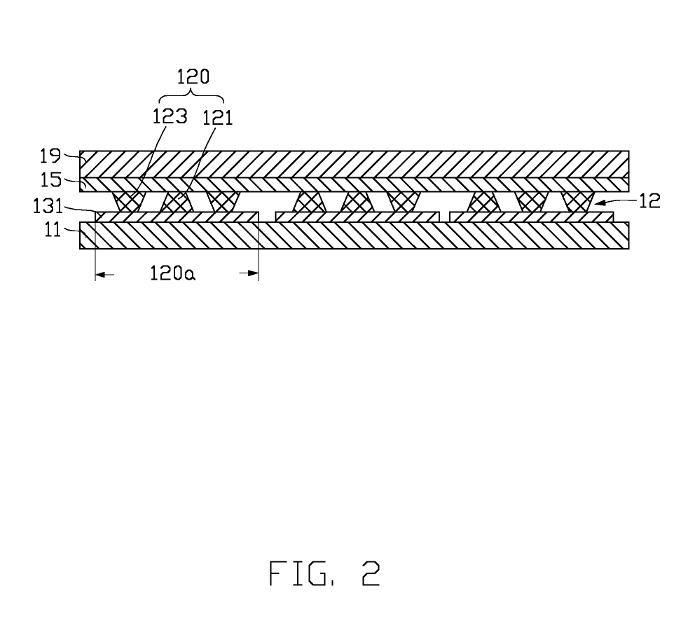

FIGS. 1-2 illustrate a planar view and a cross-sectional view, respectively, of a first exemplary embodiment of the backlight system 1. The backlight system 1 includes a backlight module 10 and a backlight driving module 90 electrically connected to the backlight module 10. The backlight module 10 includes a first substrate 11, a second substrate 19, and a light source array 12 between the first substrate 11 and the second substrate 19.

The first substrate 11 and the second substrate 19 are made of, for example, transparent glass, quartz, or plastic. Further, in other exemplary embodiments, the first substrate 11 and the second substrate 12 may be, for example, a flexible substrate. Suitable materials for the flexible substrate comprise, for example, polyethersulfone (PES), polyethylenenaphthalate (PEN), polyethylene (PE), polyimide (PI), polyvinyl chloride (PVC), polyethylene terephthalate (PET), or combinations thereof.

The light source array 12 includes a plurality of micro LEDs 120 arranged on a same layer. The light source array 12 defines a plurality of lighting regions 120a having a constant size. A number of the micro LEDs 120 in each lighting region 120a is random. A density of the micro LEDs 120 per unit area is random. In at least one exemplary embodiment, a number of the micro LEDs 120 each lighting region 120a are different from each other. In other exemplary embodiments, a number of the micro LEDs 120 in some of the lighting regions 120a are equal. In at least one exemplary embodiment, when taking along line II-II, there are three micro LEDs 120 in each of the lighting region 120a. In at least one exemplary embodiment, the backlight system 1 can also include a plurality of optical films (not shown), such as an enhancement film and a diffusion film.

The light source array 12 further includes a first conductive layer 13, a second conductive layer 15, and a plurality of first connecting lines 17.

The first conductive layer 13 can be patterned to form a plurality of first conductive units 131 in a matrix. Each first conductive unit 131 is electrically connected to the backlight driving module 90 through one of the first connecting lines 17, and corresponds to one of the lighting regions 120a. The first conductive layer 13 is located on a surface of the first substrate 11 adjacent to the second substrate 19. The first conductive layer 13 provides a first reference voltage to the micro LEDs 120. The first conductive layer 13 is made of conductive material, such as Ag, Cu, Mo, ITO, Zno, Poly(3,4-ethylenedioxythiophene) (PEDOT), carbon nanotube (CNT), Ag nano wire (ANW), graphene, or combinations thereof, but not limited.

The second conductive layer 15 is located on a surface of the second substrate 19 adjacent to the first substrate 11. The second conductive layer 15 provides a second reference voltage to the micro LEDs 120. The second reference voltage is lower than the first reference voltage, and a voltage difference is more than a threshold voltage of the micro LED 120. In at least one exemplary embodiment, the second reference voltage can be 0 volt (V). The second conductive layer 15 is made of conductive material, such as Ag, Cu, Mo, ITO, Zno, Poly(3,4-ethylenedioxythiophene) (PEDOT), carbon nanotube (CNT), Ag nano wire (ANW), graphene, or combinations thereof, but not limited.

Some of the micro LEDs 120 in the light source array 12 does not emit light. The micro LEDs 120 includes a plurality of positive micro LEDs 121 and a plurality of negative micro LEDs 123. The positive micro LEDs 121 are located in a forward direction on a surface of the first conductive unit 131, and the negative micro LEDs 123 are located in a reverse direction on a surface of the first conductive layer 131. An anode of the positive micro LED 121 is electrically connected to the first conductive unit 131, and a cathode of the positive micro LED 121 is electrically connected to the second conductive layer 15, thus the positive micro LED 121 emits light based on the first reference voltage and the second reference voltage. An anode of the negative micro LED 123 is electrically connected to the second conductive layer 15, and a cathode of the negative micro LED 123 is electrically connected to the first conductive unit 131, thus the negative micro LED 123 does not emit light. Each lighting region 120a corresponds to at least two positive micro LEDs 121 and at least one negative micro LED 123. A number of the positive micro LEDs 121 in each lighting region 120a is random, and a number of the negative micro LEDs 123 in each lighting region 120a is random too. In at least one exemplary embodiment, an emission material of the micro LED 120 is p-n diode.

In at least one exemplary embodiment, the micro LEDs 120 is formed on the first conductive unit 123 through a spraying manner to form the positive micro LEDs 121 and the negative micro LEDs 123. The spraying manner is similar to a manner to form spacers in a liquid crystal layer.

A space is defined as a distance between two midpoints of two adjacent micro LEDs 120. In at least one exemplary embodiment, the minimum space is 10 μm. In other embodiments, the minimum space is 5 μm.

In at least one exemplary embodiment, the positive micro LEDs 121 emit blue light. In other exemplary embodiments, some of the positive micro LEDs 121 emit red light, some of the positive micro LEDs 121 emit green light, and some of the positive micro LEDs 121 123 emit blue light, and a ratio of the red light, the green light, the blue light emitted by the positive micro LEDs 121 is 1:1:1.

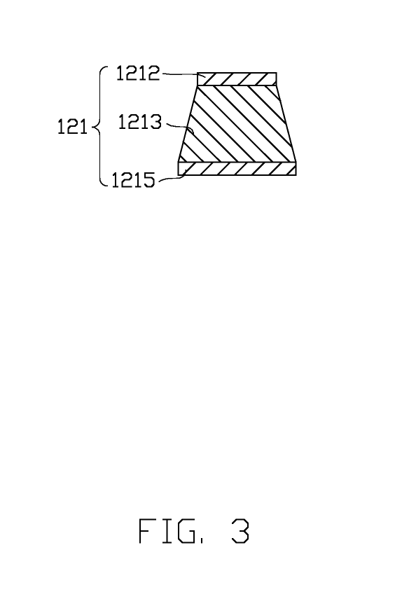

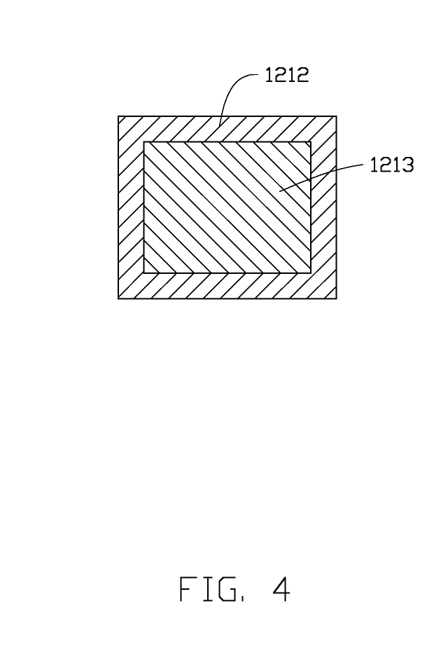

FIGS. 3-4 illustrate a cross-sectional view and a top view of the positive micro LED 121. The positive micro LED 121 includes a first electrode 1212, an emission layer 1213, and a second electrode 1215. The emission layer 1213 is located between the first electrode 1212 and the second electrode 1215. In at least one exemplary embodiment, the first electrode 1212 and the second electrode 1215 are made of metal material. When a voltage difference between a voltage applied on the first electrode 1213 and the a voltage applied on the second electrode 1215 is larger than a threshold voltage of the positive micro LED 121, the emission layer 1213 emits light. The first electrode 1212 is substantially a ring shaped. A top surface of the emission layer 1213 is exposed from the first electrode 1212. The second electrode 1215 includes a plurality of metal layers. A melting point of an outside metal layer of the second electrode 1215 is lower than a melting point of the first electrode 1212. When the positive micro LEDs 121 is located on the first conductive layer 13 through the spraying manner, the first conductive layer 13 is heated from a surface of the first conductive layer 13 without the positive micro LEDs 121 and then cooled, the outside metal layer of the second electrode 1215 is melted and then fixed on the first conductive layer 13.

The backlight driving module 90 adjusts an intensity of the micro LEDs 120 in each lighting region 120a to ensure a uniformity of the light source array 12. The detail structure of the backlight driving module 90 is described later.

Based on the structure of the backlight system, the micro LEDs do not need to be accurately placed on the first conductive layer, thus the manufacturing process of the backlight system is simplified.

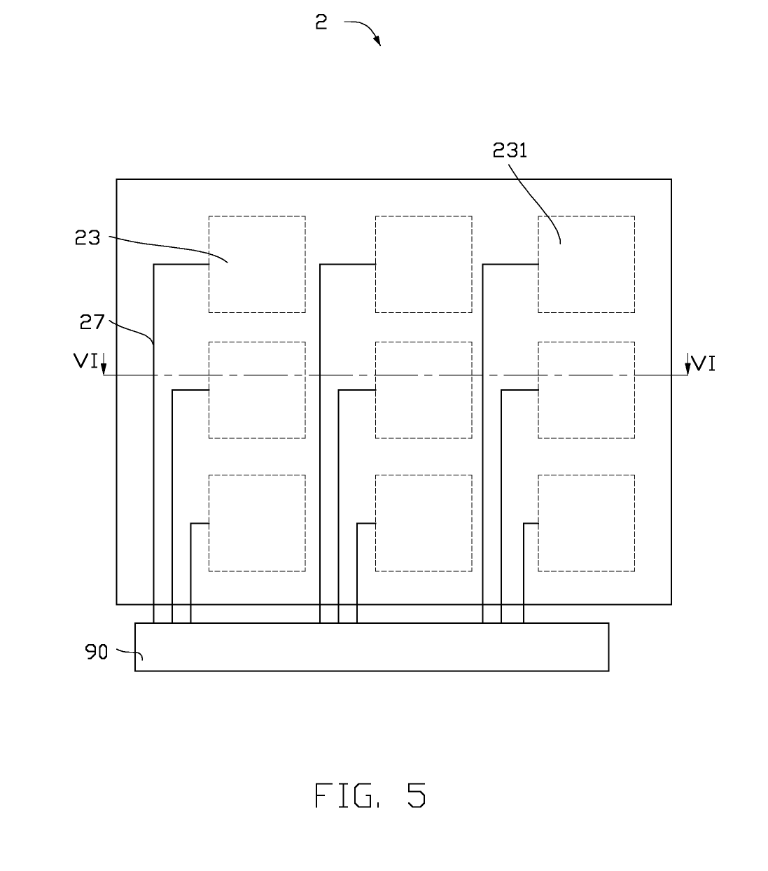

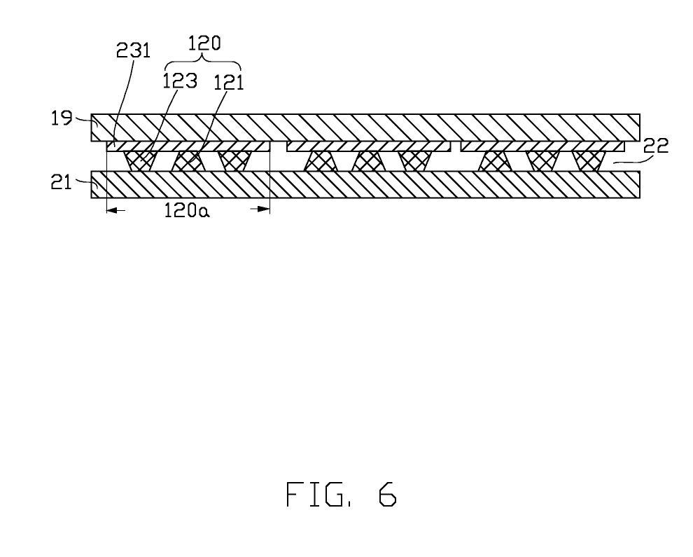

FIGS. 5-6 are a planar view and a cross-sectional view of the second exemplary embodiment of the backlight system 2. The backlight system 2 is similar to the backlight system 1. Elements in FIGS. 5-6 with the same label are same as the elements in the FIGS. 1-2. The difference between the backlight system 2 and the backlight system 1 is the first substrate 21 and the light source array 22.

The first substrate 21 is made of conductive material. In at least one exemplary embodiment, the first substrate 21 is a made of metal, such as a metal rear plate.

The light source array 22 includes a first conductive layer 23, the plurality of micro LEDs 120, and a plurality of first lines 27. The plurality of micro LEDs 120 are located between the first conductive layer 23 and the first substrate 21.

The first conductive layer 23 is patterned to form a plurality of first conductive units 231 in a matrix. Each first conductive unit 231 is electrically connected to the backlight driving module 90 through one of the first connecting lines 27.

In the second exemplary embodiment, the first substrate 21 serves as the first conductive layer 13 in the first exemplary embodiment for providing the first reference voltage, and the first conductive layer 23 serves as the second conductive layer 15 for providing the second reference voltage. The first conductive layer 23 is made of conductive material, such as Ag, Cu, Mo, ITO, Zno, Poly(3,4-ethylenedioxythiophene) (PEDOT), carbon nanotube (CNT), Ag nano wire (ANW), graphene, or combinations thereof, but not limited.

Based on the structure of the backlight system, the micro LEDs do not need to be accurately placed on the first conductive layer, thus the manufacturing process of the backlight system is simplified. Further, the first substrate serves as the first conductive layer for providing the first reference voltage, thus a thickness of the backlight system is reduced.

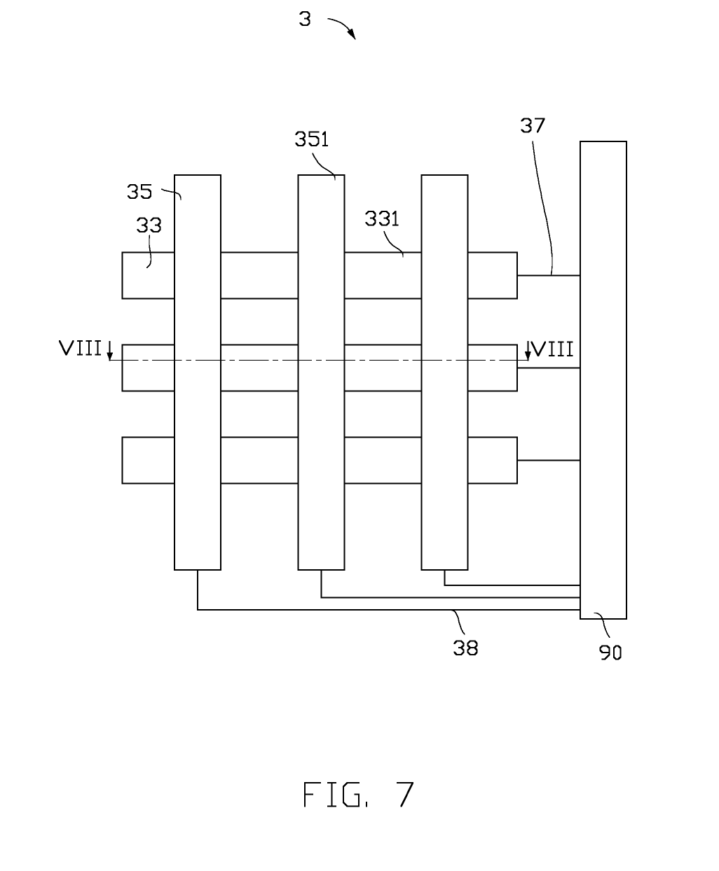

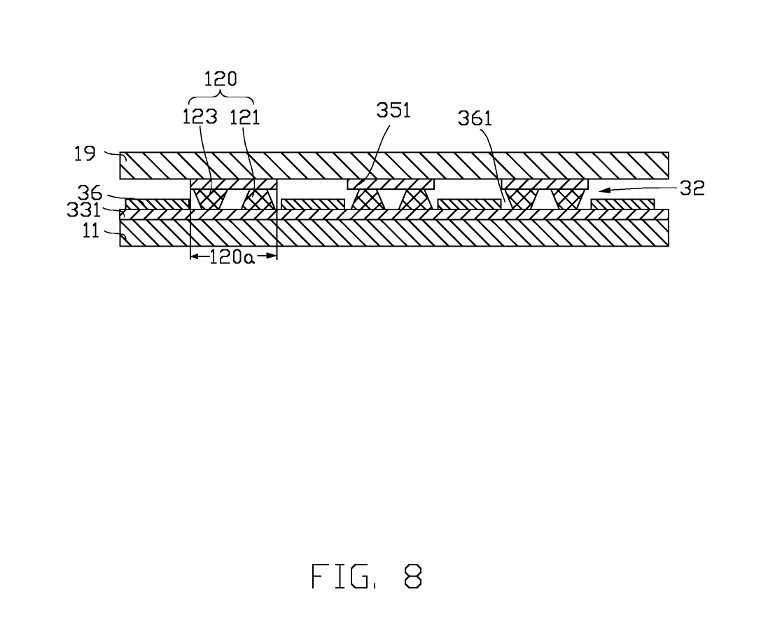

FIGS. 7-8 illustrate a planar view and a cross-sectional view of a third exemplary embodiment of the backlight system 3. The backlight system 3 is similar to the backlight system 1. Elements in FIGS. 7-8 with the same labels are the same as the elements in FIGS. 1-2. The difference between the backlight system 3 and the backlight system 1 is the light source array 32.

The light source array 32 includes a first conductive layer 33, a second conductive layer 35, an insulation layer 36, a plurality of first connecting lines 37, and a plurality of second connecting lines 38.

The first conductive layer 33 is patterned to form a plurality of first conductive units 331. The first conductive units 331 are parallel with each other along a first direction. Each first conductive unit 331 is electrically connected to the backlight driving module 90 through one of the first connecting lines 37. The second conductive layer 35 is patterned to form a plurality of second conductive units 351. The second conductive units 351 are parallel with each other along a second direction perpendicular to the first direction. Each second conductive unit 351 is electrically connected to the backlight driving module 90 through one of the second connecting lines 38. The first conductive layer 33 and the second conductive layer 35 are made of conductive material, such as Ag, Cu, Mo, ITO, Zno, Poly(3,4-ethylenedioxythiophene) (PEDOT), carbon nanotube (CNT), Ag nano wire (ANW), graphene, or combinations thereof, but not limited. The first conductive layer 33 is located on a surface of the first substrate 11 adjacent to the second substrate 19. The second conductive layer 35 is located on a surface of the second substrate adjacent to the first substrate 11. The first conductive layer 33 provides the first reference voltage, and the second conductive layer 35 provides the second reference voltage. The first reference voltage is larger than the second reference voltage, and a voltage difference between the first reference voltage and the second reference voltage is larger than a threshold voltage of the micro LED 120.

The insulation layer 36 is located between the first conductive layer 33 and the second conductive layer 35. The insulation layer 36 defines a plurality of holes 361. Each hole 361 corresponds to a junction of the first conductive unit 331 and the second conductive unit 351 along a direction of the light emitted from the backlight system 3. The micro LEDs 120 are received in the holes 361 respectively. The micro LEDs 120 form a display array served as an auxiliary display panel of the display device when the main display panel of the display device works in a standby state, and the auxiliary display panel can display predetermined content, such as a current time, a coming call, or a received text.

Based on the structure of the backlight system, the micro LEDs do not need to be accurately placed on the first conductive layer, thus the manufacturing process of the backlight system is simplified. The micro LEDs also can served as an auxiliary display panel of the display device where the backlight system is embedded, thus a performance of the backlight system is improved.

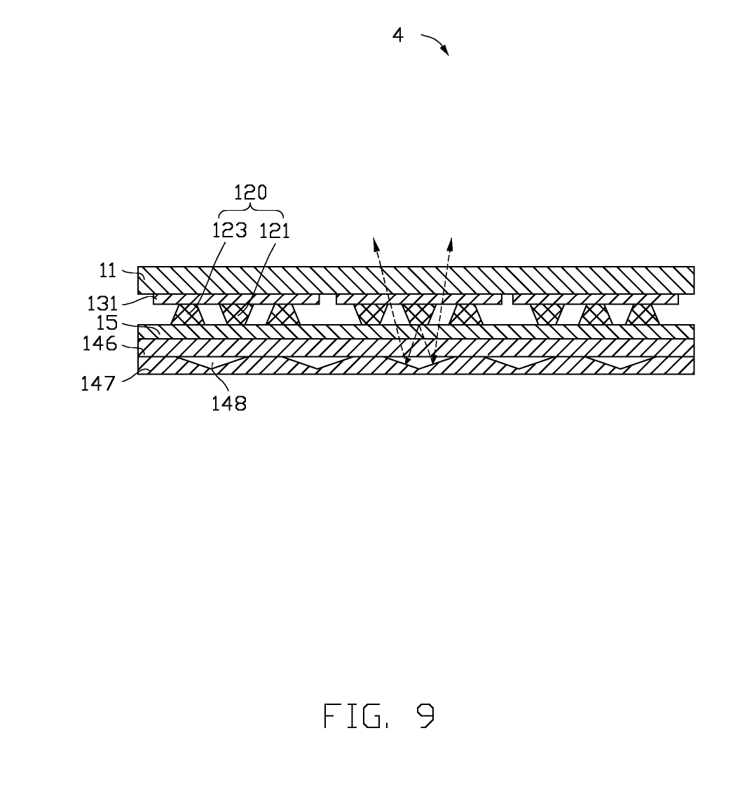

FIG. 9 illustrates a fourth exemplary embodiment of the backlight system 4. The backlight system 4 is similar to the backlight system 1, but is shown in a reversed direction. Elements in FIG. 9 with the same label are same as the elements in the FIG. 2. The difference between the backlight system 4 and the backlight system 1 is the backlight module 10. The backlight module 10 further includes a quantum dots layer 146 and a reflector plate 147.

The quantum dots layer 146 is located on a surface of the second conductive layer 15 away from the first conductive layer 13. The light emitted by the positive micro LED 121 passes through the second conductive layer 15 to the quantum dots layer 146. The quantum dots layer 146 converts wavelengths of the light emitted by the positive micro LED 121. The quantum dots layer 146 can include a plurality of first quantum dots and a plurality of second quantum dots. The first dots are used for converting the wavelengths of the light into a first wavelength of the light, such as the wavelength of the red light, and the second dots are used for converting the wavelengths of the light into a second wavelength of the light, such as the wavelength of green light.

The reflector plate 147 is located on a surface of the quantum dots layer 146 away from the second conductive layer 15. The reflector plate 147 reflects the light emitted from the quantum dots layer 146 back to the first substrate 11 for coming out of the backlight module 10. The lights coming out of the backlight module 10 are mixed as a white light. The reflector plate 147 includes a plurality of concave portions 148. The concave portions 148 are concaved from a surface of the reflector plate 147 to an opposite surface of the reflector plate 147. A cross section of the concave portion 148 is substantially triangle shape. In other exemplary embodiments, the cross section of the concave portion 148 can be an arc shaped or a polygon shaped.

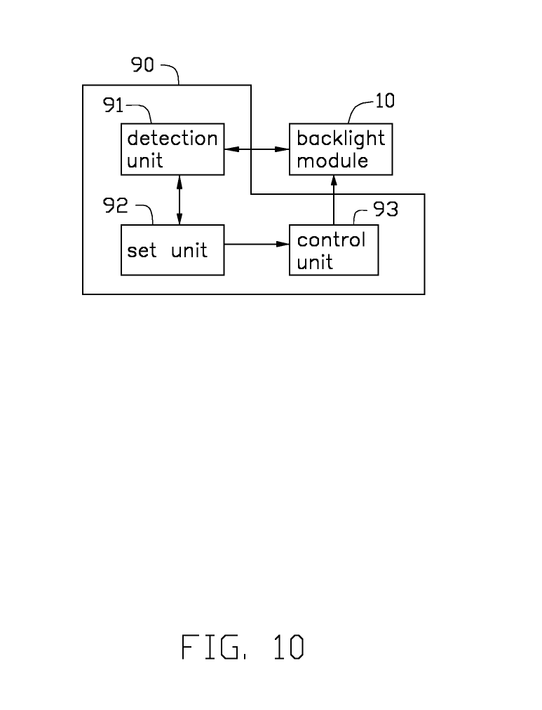

FIG. 10 illustrates the backlight driving module 90. The backlight driving module 90 is embedded in a display device which can operate in a display state and the standby state.

The backlight driving module 90 includes a detection unit 91, a set unit 92, and a control unit 93. The detection unit 91 provides the first reference voltage to the first conductive layer 13, and the second reference voltage to the second conductive layer 15, and detects an intensity of each lighting region 120a.

The set unit 92 pre-stores a predetermined intensity. The set unit 92 compares the detected intensity of each lighting region 120a and the predetermined intensity, and adjusts a parameter corresponding to each lighting region 120a based on the comparison result. In at least one exemplary embodiment, the parameter is the reference voltage. When the detected intensity of the lighting region 120a is less than the predetermined intensity, the number of the positive micro LEDs 120 in the corresponding lighting region 120a is insufficient, and the set unit 92 adjusts the parameter for increasing the intensity of the corresponding lighting region 120a. When the detected intensity of the lighting region 120a is more than the predetermined intensity, the number of the positive micro LEDs 120 in the corresponding lighting region 120a is excessive, and the set unit 92 adjusts the parameter for decreasing the intensity of the corresponding lighting region 120a.

The control unit 93 adjusts a grayscale of each first conductive unit 131 based on the adjusted parameter in the display state. The control unit 93 further can controls the light source array 12 to emit light for displaying predetermined content when the display device is in the standby state.

Based on the structure of the backlight system, the micro LEDs do not need to be accurately placed on the first conductive layer, thus the manufacturing process of the backlight system is simplified. The intensity of the backlight module is constant, thus a performance of the backlight system is improved.

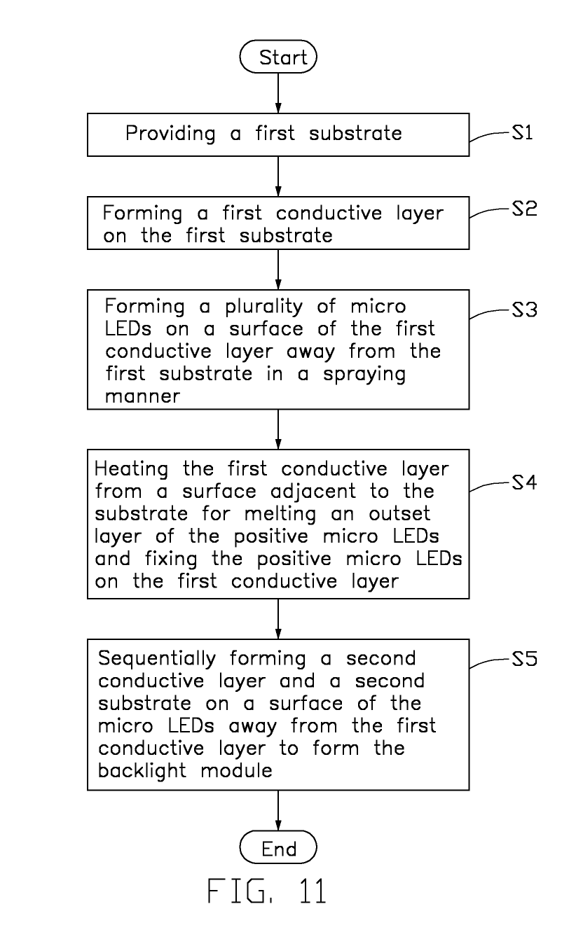

FIG. 11 illustrates a flowchart is presented in accordance with an example exemplary embodiment. The method is provided by way of example, as there are a variety of ways to carry out the method. The method described below can be carried out using the configurations illustrated in FIGS. 1-2, for example, and various elements of these figures are referenced in explaining the method. Each block shown in FIG. 11 represents one or more processes, methods or subroutines, carried out in the method. Furthermore, the order of blocks is illustrative only and the order of the blocks can change according to the present disclosure. Additional blocks can be added or blocks can be removed, without departing from this disclosure. The method can begin at block S1.

At block S1, providing a first substrate 11.

At block S2, forming a first conductive layer 13 on a surface of the first substrate 11. The first conductive layer 13 can be patterned to form a plurality of first conductive units 131.

At block S3, forming a plurality of micro LEDs 120 on a surface of the first conductive layer away from the first substrate 11 in a spraying manner to form a plurality of positive micro LEDs 121 and a plurality of negative micro LEDs 123. The spraying manner is similar to a manner of forming spacers in a liquid crystal layer.

At block S4, heating the first conductive layer 13 from a surface adjacent to the substrate 11 for melting an outside layer of the positive micro LEDs 121 and fixing the positive micro LEDs 121 on the first conductive layer 13.

At block S5, sequentially forming a second conductive layer 15 and a second substrate 19 on a surface of the micro LEDs 120 away from the first conductive layer 13 to form the backlight module 10.

In use, the method for manufacturing the micro LEDs is simple.

While various exemplary and preferred exemplary embodiments have been described the disclosure is not limited thereto. On the contrary, various modifications and similar arrangements (as would be apparent to those skilled in the art) are also intended to be covered. Therefore, the scope of the appended claims should be accorded the broadest interpretation so as to encompass all such modifications and similar arrangements.

What is claimed is:

1. A backlight system comprising:
a backlight module for providing backlight, the backlight module comprising:
a light source array with a plurality of micro LEDs;
wherein the backlight module defines a plurality of lighting regions having a constant size; a number of the micro LEDs in each lighting region is random; the micro LEDs in each lighting region comprises a plurality of positive micro LEDs located in a forward manner and a plurality of negative micro LEDs located in a reverse manner.

2. The backlight system of claim 1, wherein the light source array further comprises a first substrate, a first conductive layer, and a second conductive layer; the first conductive layer is located between the first substrate and the light source array; the second conductive layer is located on a surface of the light source array away from the first conductive layer; the micro LEDs are electrically connected with the first conductive and the second conductive layer; the first substrate is made of insulation material.

3. The backlight system of claim 2, wherein the first conductive layer provides a first reference voltage to the micro LEDs; the second conductive layer provides a second reference voltage to the micro LEDs; the first reference voltage is larger than the second reference voltage; a voltage difference between the first reference voltage and the second reference voltage is larger than a threshold voltage of micro LEDs.

4. The backlight system of claim 3, wherein an anode of the positive micro LED is electrically connected to the first conductive layer, a cathode of the positive micro LED is electrically connected to the second conductive layer; an anode of the negative micro LED is electrically connected to the second conductive layer, a cathode of the negative micro LED is electrically connected to the first conductive layer; the positive micro LED emits light based on the first reference voltage and the second reference voltage; the negative micro LED does not emit light based on the first reference voltage and the second reference voltage.

5. The backlight system of claim 2, wherein the first conductive layer comprises a plurality of first conductive units in a matrix; each first conductive unit corresponds to one of lighting regions; the first conductive units receives different first reference voltage for adjusting the intensity of the corresponding lighting region.

6. The backlight system of claim 2, wherein the light source array further comprises an insulation layer; the first conductive layer comprises a plurality of first conductive units; the first conductive units are parallel with each other along a first direction; the second conductive layer comprises a plurality of second conductive units; the second conductive units are parallel with each other along a second direction perpendicular to the first direction; the insulation layer defines a plurality of holes; each hole is located at a junction of the first conductive units and the second conductive units; each micro LED is received in one of the holes.

7. The backlight system of claim 6, wherein an anode of the positive micro LED is electrically connected to the first conductive unit, a cathode of the positive micro LED is electrically connected to the second conductive unit; an anode of the negative micro LED is electrically connected to the second conductive unit, a cathode of the negative micro LED is electrically connected to the first conductive unit; the positive micro LED emits light based on the first reference voltage and the second reference voltage; the negative micro LED does not emit light based on the first reference voltage and the second reference voltage.

8. The backlight system of claim 2, wherein the light source array further comprises a quantum dots layer; the quantum dots layer is located on a surface of the second conductive layer away from the first conductive layer; the quantum dots layer converts wavelength of the light emitted by the micro LEDs.

9. The backlight system of claim 8, wherein the light source array further comprises a reflector plate; the reflector plate is located on a surface of the quantum dots layer away from the second conductive layer; the reflector plate reflects the light emitted by the quantum dots layer to the first substrate.

10. The backlight system of claim 9, wherein the reflector plate includes a plurality of concave portions; the concave portions are concaved from a surface of the reflector plate adjacent to the quantum dots layer to a surface of the reflector away from the quantum dots layer.

11. The backlight system of claim 1, wherein the light source array further comprises a first substrate and a first conductive layer; the first substrate is made of conductive material; the light source array is located between the first substrate and the first conductive layer; the micro LEDs are electrically connected with the first substrate and the first conductive layer; the first substrate provides a first reference voltage to the micro LEDs; the first conductive layer provides a second reference voltage to the micro LEDs; the first reference voltage is larger than the second reference voltage; a voltage difference between the first reference voltage and the second reference voltage is larger than a threshold voltage of micro LEDs.

12. The backlight system of claim 11, wherein an anode of the positive micro LED is electrically connected to the first substrate, a cathode of the positive micro LED is electrically connected to the first conductive layer; an anode of the negative micro LED is electrically connected to the first conductive layer, a cathode of the negative micro LED is electrically connected to the first substrate; the positive micro LED emits light based on the first reference voltage and the second reference voltage; the negative micro LED does not emit light based on the first reference voltage and the second reference voltage.

13. The backlight system of claim 1, wherein the micro LED comprises a first electrode, an emission layer, and a second electrode with multiple layers; the emission layer is located between the first electrode layer and the second electrode layer; a melting point of an outside layer of the second electrode layer is lower than a melting point of the first electrode.

14. The backlight system of claim 1, wherein the backlight system further comprises a backlight driving module; the backlight driving module adjusts an intensity of each lighting regions for achieving a uniformity intensity of the backlight system; the backlight module comprises a detection unit, a set unit, and a control unit; the detection unit detects an intensity of each lighting region; the set unit pre-stores a predetermined intensity; the set unit compares the detected intensity of each lighting region with the predetermined intensity and adjusts a parameter corresponding to each lighting region based on the comparison result; when the detected intensity of the lighting region is less than the predetermined intensity, the number of the positive micro LEDs in the corresponding lighting region is insufficient, and the set unit adjusts the parameter for increasing the intensity of the corresponding lighting region; when the detected intensity of the lighting region is more than the predetermined intensity, the number of the positive micro LEDs in the corresponding lighting region is excessive, and the set unit adjusts the parameter for decreasing the intensity of the corresponding lighting region; the control unit controls a grayscale of each first conductive unit based on the adjusted parameter.

15. The backlight system of claim 1, wherein some of the positive micro LEDs emit red light, some of the positive micro LEDs emit green light, and some of the positive micro LEDs 121 emit blue light, and a ratio of the red light, the green light, the blue light of the positive micro LEDs is 1:1:1.

16. A method for manufacturing a backlight module of a backlight system, the method comprising:
providing a first substrate;
forming a first conductive layer on the first substrate;
forming a plurality of micro LEDs on a surface of the first conductive layer away from the first substrate in a spraying manner;
heating the first conductive layer from a surface adjacent to the substrate for melting an outside layer of the positive micro LEDs and fixing the positive micro LEDs on the first conductive layer; and
sequentially forming a second conductive layer and a second substrate on a surface of the micro LEDs away from the first conductive layer to form the backlight module.
